(19) United States
(12) Patent Application Publication
(10) Pub. No.: US 2005/0048783 A1
(43) Pub. Date: Mar. 3, 2005

(54) Method for planarizing a surface of a semiconductor wafer

(75) Inventor: Ji Myong Lee, Seoul (KR)

Correspondence Address: PILLSBURY WINTHROP, LLP, P.O. BOX 10500, MCLEAN, VA, 22102, US

(73) Assignee: Dongbu Electronics Co., Ltd., Seoul (KR)

(21) Appl. No.: 10/743,454

(22) Filed: Dec. 23, 2003

(30) Foreign Application Priority Data
Sep. 1, 2003 (KR) 10-2003-0060850

(51) Int. Cl. H01L 21/302; H01L 21/4763; H01L 21/461

(52) U.S. Cl. 438/693; 438/633

(57) ABSTRACT

In a method for polishing a surface of a semiconductor wafer, a first polishing process using slurry is performed on a surface of the insulator layer after an insulator layer is deposited on the semiconductor wafer. Subsequently, a second polishing process using water instead of the slurry is performed on the surface of the insulator layer. As a result, the production cost is decreased and many defects resulting from the scratches are prevented.

### FIELD OF THE INVENTION

The present invention relates to a method for planarizing a surface of a semiconductor wafer; and, more particularly, to a method for planarizing a surface of a semiconductor wafer without causing scratches thereon by performing a water polishing process using water after a chemical mechanical polishing (hereinafter referred to as “CMP”) process using slurry.

### BACKGROUND OF THE INVENTION

In manufacturing a semiconductor device such as a CPU and a memory device, an entire surface of a semiconductor wafer is polished and planarized by a CMP process. At present, only such CMP technique provides a total planarization of the semiconductor wafer.

In the CMP process, the surface of the semiconductor wafer to be polished is face-down disposed on a rotatable polishing pad of a CMP apparatus. During the CMP process, a chemical agent referred to as slurry is supplied on the semiconductor wafer, e.g., between the surface thereof and the polishing pad in order to help the polishing pad to polish the surface of the semiconductor wafer.

The slurry may be, e.g., a compound of colloid silica, dispersed alumina and alkaline solution such as KOH, NH₄OH, or CeO₂ base slurry. Essentially, particles of colloidal silica and dispersed alumina, which have a great abrasive property, are capable of facilitating the polishing of the surface of the semiconductor wafer.

After completion of the CMP process, slurry residues on the polishing pad should be eliminated by cleaning before a subsequent CMP process is performed on a next wafer.

There have been proposed various techniques for cleaning the slurry residues remaining on the polishing pad after completion of the CMP process. Such techniques, however, have a limitation in cleaning or eliminating all the slurry residues.

In case a small amount of the slurry residues still remain on the polishing pad and are dried out, the slurry residues may cause scratches on the next wafer disposed on the polishing pad for a subsequent CMP process, thereby deteriorating a yield of the wafer.

### SUMMARY OF THE INVENTION

It is, therefore, an object of the present invention to provide a method for planarizing a surface of a semiconductor wafer, wherein a water polishing process using water is performed after a conventional CMP process using slurry, thereby preventing scratches on the semiconductor wafer and increasing a yield of the semiconductor wafer.

In accordance with a preferred embodiment of the present invention, there is provided a method for polishing a surface of a semiconductor wafer. In such a method, an insulator layer is deposited on the surface of the semiconductor wafer and a first polishing process using slurry is performed on the semiconductor wafer. Then, a second polishing process using water instead of the slurry is performed on the surface of the insulator layer in a same chamber in which the first polishing process is performed.

### BRIEF DESCRIPTION OF THE DRAWINGS

The above and other objects and features of the present invention will become apparent from the following description of preferred embodiments, given in conjunction with the accompanying drawings, in which;

FIG. 1 is a flow chart representing a process of planarizing a wafer in accordance with a preferred embodiment of the present invention;

FIG. 2A shows a graph of removal amounts in a first polishing process using slurry;

FIG. 2B illustrates a graph of removal amounts in a second polishing process by using water in accordance with the preferred embodiment of the present invention;

FIG. 2C depicts a graph of total removal amounts in the first and the second polishing process.

### DETAILED DESCRIPTION OF THE PREFERRED EMBODIMENTS

A preferred embodiment of the present invention will now be described in detail with reference to the accompanying drawings, wherein like reference numerals appearing in the drawings represent like parts.

Main features of the present invention are as follows: A predetermined thickness (about 80% thickness of a total polishing target) of an insulator layer is removed by performing a main polishing process, i.e., a first polishing process using slurry, and the remainder (about 20% thickness of the total polishing target) of the insulator layer is polished by performing a water polishing process, i.e., a second polishing process using water instead of slurry.

In order to perform the water polishing process in accordance with the present invention, an oxide film should be formed in advance. For this purpose, an IMD (inter metal dielectric) layer, which is formed after a STI (shallow trench isolation) process, is used as the oxide film. The IMD layer is made of O₃—TEO, USG (undoped silicate glass), FSG (fluorinated silicate glass), TEOS (tetraethoxysilicate), SiH or the like.

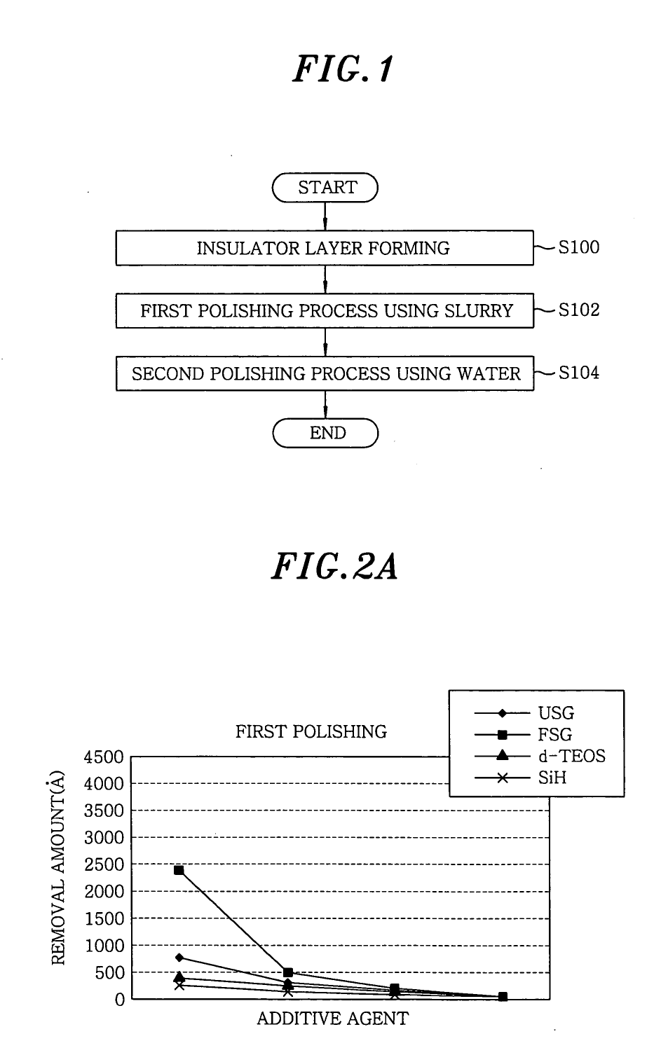

FIG. 1 is a flow chart representing a process of planarizing a semiconductor wafer in accordance with the present invention.

First, in step S100, an insulator layer is deposited on a semiconductor wafer by a CVD (chemical vapor deposition) process. Subsequently, a planarization thereof is performed by a CMP process. At this time, the planarization is performed in two stages, i.e., a first polishing process (main polishing process) using slurry and a second polishing process (water polishing process) using water instead of the slurry. The second polishing process is carried out immediately after the first polishing process.

A removal amount (unit: Å) of the insulator layer in each process is indicated in Table 1.

TABLE 1

Insulator type

| Polishing step | FSG | USG | SiH | TEOS |
|---|---|---|---|---|
| First polishing (main) | 2400 | 800 | 300 | 400 |
| Second polishing (water) | 1200 | 1200 | 200 | 80 |
| Total polishing | 3600 | 2000 | 500 | 480 |
| (main + water) | | | | |

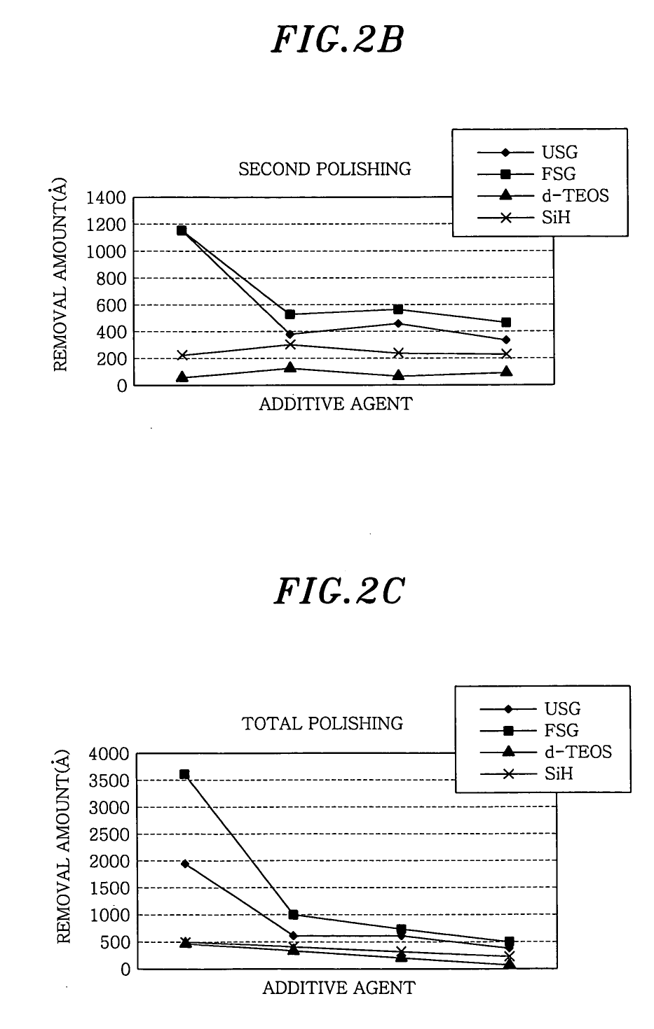

Specifically, in step S102, while supplying slurry to a surface of the insulator layer, e.g., between the surface of the insulator layer and a polishing pad of a CMP apparatus, the first polishing process is performed. In this case, a part of a total polishing target of the insulator layer is removed. The removed part of the total polishing target in the first polishing process depends on a type of the insulator layer and a removal amount for each insulator layer type in the first polishing process is shown in FIG. 2A.

Subsequently, in step S104, the second polishing process is performed on the surface of the insulator layer in order to polish the remainder of the total polishing target by using water instead of the slurry. A removal amount for each insulator layer type in the second polishing process is illustrated in FIG. 2B.

As a result, the total removal amount of the insulator layer in the planarization process is as shown in FIG. 2C.

In accordance with the process of the present invention, since the insulator layer is polished by the water polishing process, the production cost thereof is decreased compared with the conventional CMP process using only slurry and scratches on the semiconductor wafer due to slurry residues are prevented.

While the invention has been shown and described with respect to the preferred embodiments, it will be understood by those skilled in the art that various changes and modifications may be made without departing from the spirit and scope of the invention as defined in the following claims.

1. A method for planarizing a surface of a semiconductor wafer, comprising:
depositing an insulator layer on the semiconductor wafer;
performing a first polishing process on a surface of the insulator layer deposited on the semiconductor wafer while supplying slurry to the surface of the insulator layer; and
performing a second polishing process on the surface of the insulator layer while supplying water to the surface of the insulator layer.

2. The method of claim 1, wherein the insulator layer is an inter metal dielectric (“IMD”) layer.

3. The method of claim 2, wherein the IMD layer is made of fluorinated silicate glass (“FSG”), undoped silicate glass (“USG”), tetraethoxysilicate (“TEOS”) or SiH.

4. the method of claim 1, wherein about 80% thickness of a total polishing target of the insulator layer is removed by the first polishing process and the remainder of the insulator layer is polished by the second polishing process.
